(19) United States
(12) Patent Application Publication
(10) Pub. No.: US 2010/0212100 A1
(43) Pub. Date: Aug. 26, 2010

(54) Cleaning Apparatus for Sophisticated Electric Device

(75) Inventors: Chih-An Ku, Hsinchu City (TW); Terry Cheng, Hsinchu City (TW); Roy Chen, Zhubei City (TW)

Correspondence Address: Jackson Intellectual Property Group PLLC, 106 Starvale Lane, Shipman, VA, 22971, US

(73) Assignee: TUNG AN DEVELOPMENT LTD., Hsinchu County (TW)

(21) Appl. No.: 12/685,269

(22) Filed: Jan. 11, 2010

(30) Foreign Application Priority Data
Feb. 26, 2009 (TW) 098202863

(51) Int. Cl. B08B 1/00

(52) U.S. Cl. 15/244.1

(57) ABSTRACT

A cleaning apparatus is provided to clean a sophisticated electric device. The apparatus has cleaning units and each of the cleaning units has a cambered top. Thus, coordinated with an actuating device, a sophisticated electric device can be cleaned by using the cleaning apparatus with cleaning units having cambered tops.

### FIELD OF THE INVENTION

The present invention relates to cleaning a sophisticated electric device; more particularly, relates to obtaining a big surface contact area, a fast cleaning velocity and a high decontamination rate on using a cleaning apparatus with cleaning units having cambered tops to clean a surface of a sophisticated electric device with coordination of an actuating device.

### DESCRIPTION OF THE RELATED ARTS

A first prior art of a cleaning device is made of elastic polyvinyl alcohol (PVA) sponge with a number of outgrowths on a side surface, where tops of the outgrowths are smooth and the cleaning device is rotated to touch and clean a surface of an electric device with the tops of the outgrowths. Thus, coordinated with an actuating device, the electric device can be cleaned by using the first prior art with the outgrowths.

A second prior art of a cleaning device comprises a base and a porous material, where the base has an inner surface and an outer surface; the porous material covers at least a part of the outer surface of the base to be combined with the base; the base has a number of protrusions; and the protrusions of the base are set correspondingly to the surface of the porous material. Thus, coordinated with an actuating device, the electric device can be cleaned by using the second prior art with the protrusions.

The above prior arts can be used to clean the electric device. But, in the first prior art, each outgrowth has a very smooth top and the top is flat; and, in the second prior art, each protrusion also has a flat top. These prior arts do not effectively touch and clean the electric device which may have an unsmooth surface. Hence, the prior arts do not fulfill all users' requests on actual use.

### SUMMARY OF THE INVENTION

The main purpose of the present invention is to obtain a big surface contact area, a fast cleaning velocity and a high decontamination rate on using a cleaning apparatus with cleaning units having cambered tops to clean a surface of a sophisticated electric device with coordination of an actuating device.

To achieve the above purpose, the present invention is a cleaning apparatus for a sophisticated electric device, comprising a carrier, and a plurality of cleaning units, where the plurality of cleaning units is deposed on a surface of the carrier; each of the cleaning units has a cambered top on an end surface; and the cambered top has a curve ratio between 70 percents (%) and 99%. Accordingly, a novel cleaning apparatus for a sophisticated electric device is obtained.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is the perspective view showing the first preferred embodiment according to the present invention;

FIG. 2 is the sectional view showing the first preferred embodiment;

FIG. 3 is the view showing the state of use of the first preferred embodiment;

FIG. 4 is the perspective view showing the second preferred embodiment; and

FIG. 5 is the view showing the state of use of the second preferred embodiment.

### DESCRIPTION OF THE PREFERRED EMBODIMENTS

The following descriptions of the preferred embodiments are provided to understand the features and the structures of the present invention.

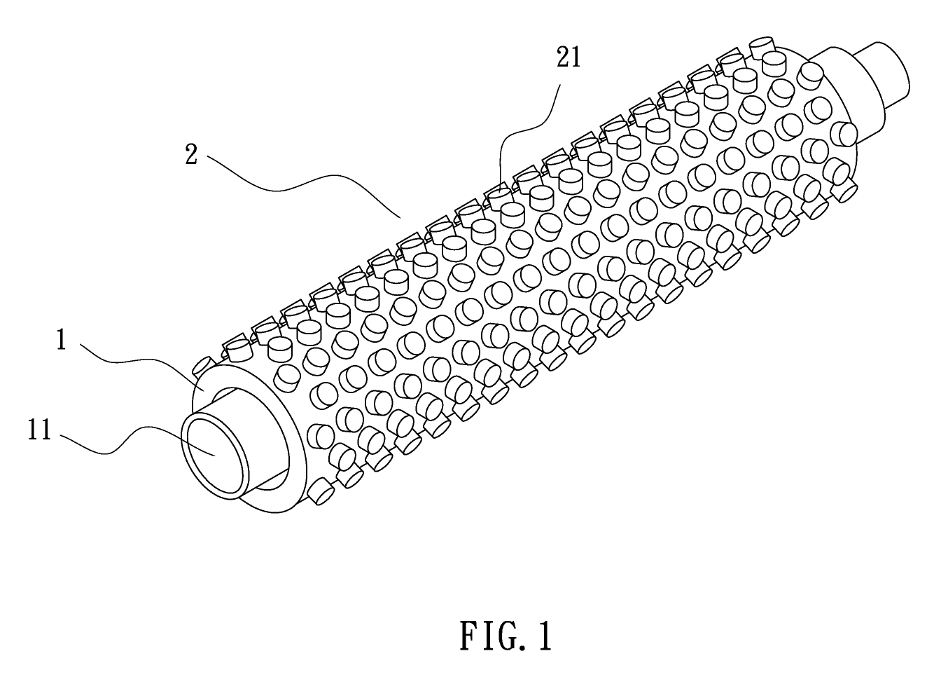

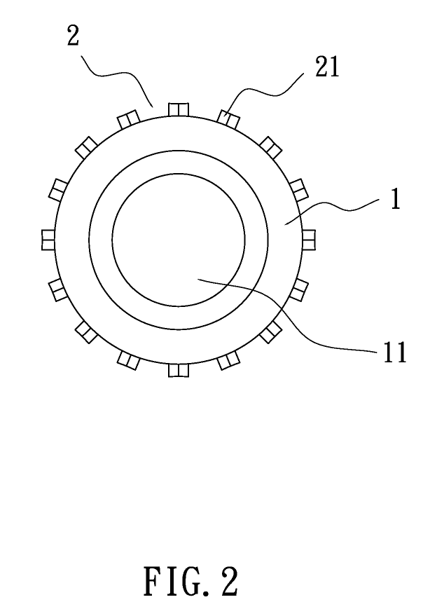

Please refer to FIG. 1 and FIG. 2, which are a perspective view and a sectional view showing a first preferred embodiment according to the present invention. As shown in the figures, the present invention is a cleaning apparatus for a sophisticated electric device, comprising a carrier 1 and a plurality of cleaning units 2, where the carrier 1 and the plurality of cleaning units 2 are made into a whole one and are made of a composite material, sponge, polyurethane (PU), polyvinyl alcohol (PVA) or a polymer material.

The carrier 1 is a circular column and has a sheathing part 11 within at center.

The plurality of cleaning units 2 is deposed on an outside surface of the carrier 1, where the cleaning units 2 are circular columns or polygon columns; each of the cleaning units 2 has a cambered top 21 on an end surface; and the cambered top 21 has a curve ratio between 70 percents (%) and 99%.

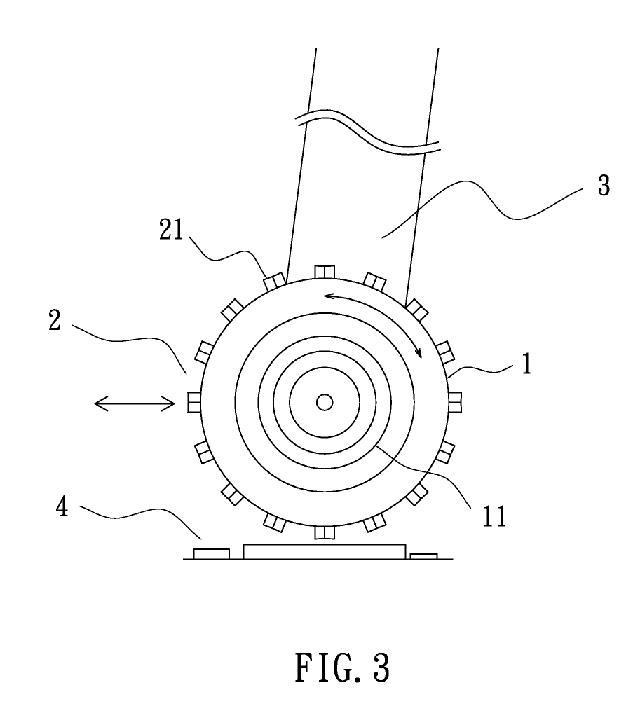

Please refer to FIG. 3, which is a view showing a state of use of the first preferred embodiment. As shown in the figure, on using the first preferred embodiment, an actuating device 3 is combined with a carrier 1 or a plurality of carriers 1 through each sheathing part 11 of the carrier 1. The actuating device 3 rolls the carrier 1 to move to a position for cleaning a sophisticated electric device 4, where each of the cleaning units 2 of the carrier 1 has a cambered top 21; and the cleaning units 2 are contacted with a surface of the sophisticated electric device 4 for required cleaning. Because the cambered top 21 has a curve ratio between 70% and 90%, the cleaning units 2 obtain a big surface contact area, a fast cleaning velocity and a high decontamination rate.

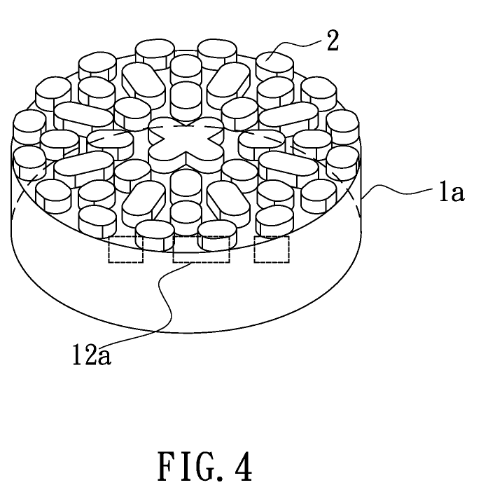

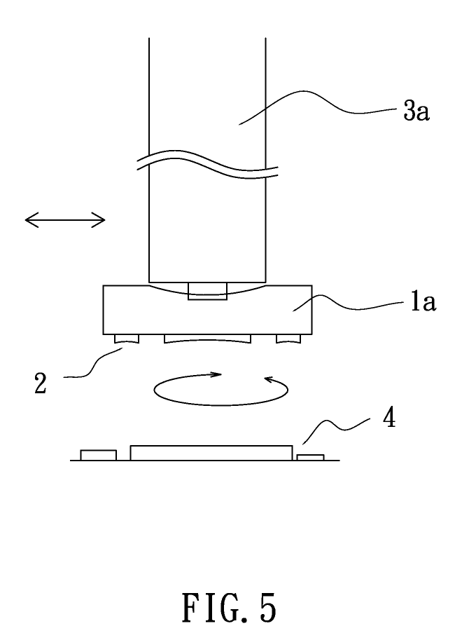

Please refer to FIG. 4 and FIG. 5, which are a perspective view showing a second preferred embodiment; and a view showing a state of use of the second preferred embodiment. As shown in the figures, a carrier 1 a of a second preferred embodiment is a disk, where a plurality of cleaning units 2 is deposed on a surface of the carrier 1 a; an assembling part 12a is set on another surface of the carrier 1a; and the cleaning units 2 are circular columns and/or polygon columns.

On using the second preferred embodiment, an actuating device 3a is combined with the carrier 1a or a plurality of the carriers 1a through each assembling part 12a of the carrier 1a. The actuating device 3a rotates the carrier 1a or the plurality of the carriers 1a to move to position for cleaning a sophisticated electric device 4, where the cleaning units 2 of each carrier 1 a are contacted with a surface of the sophisticated electric device 4 for required cleaning.

To sum up, the present invention is a cleaning apparatus for a sophisticated electric device, where a big contact area, a fast cleaning velocity and a high decontamination rate are obtained by using cleaning units having cambered tops on cleaning a surface of a sophisticated electric device with coordination of an actuating device.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A cleaning apparatus for a sophisticated electric device, comprising
a carrier, and
a plurality of cleaning units, said plurality of cleaning units being deposed on a surface of said carrier;
wherein each of said cleaning units has a cambered top on an end surface; and
wherein said cambered top has a curve ratio between 70 percents (%) and 99%.

2. The cleaning apparatus according to claim 1,
wherein said carrier is a circular column;
wherein said circular column has a sheathing part within at center; and
wherein said plurality of cleaning units is deposed on an outside surface of said carrier.

3. The cleaning apparatus according to claim 1,
wherein said carrier is a disk;
wherein said plurality of cleaning units is deposed on a surface of said carrier.
wherein an assembling part is deposed on another surface of said carrier.

4. The cleaning apparatus according to claim 1,
wherein said carrier and said plurality of cleaning units are made into a whole one.

5. The cleaning apparatus according to claim 1,
wherein said carrier and said plurality of cleaning units are made of a material selected from a group consisting of a composite material, sponge, polyurethane (PU), polyvinyl alcohol (PVA) and a polymer material.

6. The cleaning apparatus according to claim 1,
wherein said cleaning units are circular columns.

7. The cleaning apparatus according to claim 1,
wherein said cleaning units are polygon columns.

8. The cleaning apparatus according to claim 1,
wherein said cleaning units are circular columns and polygon columns.
